(19) United States
(12) Patent Application Publication
(10) Pub. No.: US 2026/0370206 A1
(43) Pub. Date: Nov. 19, 2026

(54) SYSTEMS AND METHODS FOR BALUNS OPTIMIZED FOR WIDEBAND BALANCED PROPERTIES

(71) Applicant: TTM TECHNOLOGIES NORTH AMERICA, INC., Santa Ana, CA (US)

(72) Inventors: Chong Mei, Santa Ana, CA (US); Omar Eldaiki, Santa Ana, CA (US)

(21) Appl. No.: 19/142,627

(22) PCT Filed: Dec. 21, 2023
(86) PCT No.: PCT/US2023/085487

§ 371 Date: Jun. 23, 2025

Related U.S. Application Data
(60) Provisional application No. 63/476,539, filed on Dec. 21, 2022.

(51) Int. Cl. H03H 7/42

(52) U.S. Cl. CPC H03H 7/42

(57) ABSTRACT

A balun circuit addresses the balun bandwidth problem using a symmetrical amplitude splitting network and a phase delay network for conversion of a single-ended signal to a differential signal. As the balancing properties of the balun circuit are guaranteed in a very wide bandwidth, other performance properties such as impedance matching and insertion loss which can also limit the operating bandwidth, can be addressed separately with the full attention without the concerns of phase and amplitude balance. The balun circuit divides the single-ended signal into a four-path differential signal through a symmetric network and applies phase inversion by twisting the polarities of each differential path to reduce the complexity, size and loss of the overall balun of the balun circuit.

### CROSS REFERENCE TO RELATED APPLICATION

The present application claims priority to U.S. Provisional Application No. 63/476,539 filed Dec. 21, 2022; the contents of which are incorporated herein in its entirety.

### FIELD

The present disclosure generally relates to signal conversion, and in particular, to a system and associated method for conversion of a single-ended source signal to a differential signal using baluns optimized for wideband balance.

### BACKGROUND

Baluns are used to convert signals from single-ended signals to differential signals. The bandwidth of a balun is limited by various factors including circuit topology, material properties, package parasitics, and other associated design constraints such as size, loss and cost. When designing a system for converting single-ended signals to differential signals for analog-to-digital conversion applications, designers must consider these factors to carefully balance the system. Conventional solutions of directly converting a single-ended source signal to generate a differential signal is an imperfect solution as this type of system can be difficult to balance and can result in a sub-optimal differential signal.

It is with these observations in mind, among others, that various aspects of the present disclosure were conceived and developed.

### BRIEF DESCRIPTION OF THE DRAWINGS

FIGS. 1A-1E are a series of schematic diagrams showing a balun circuit for conversion of a single-ended signal to a differential signal;

FIGS. 2A-2D are a series of graphical representations respectively showing amplitude imbalance, phase imbalance, return loss, and insertion loss for a conventional 1:2 Marchand balun and a conventional 1:1 Guanella balun;

FIG. 3 shows a first example balun circuit for implementation of the balun circuit of FIGS. 1A-1E;

FIGS. 4A-4D are a series of graphical representations respectively showing amplitude imbalance, phase imbalance, return loss, and insertion loss for the first example balun circuit of FIG. 3;

FIG. 5 shows a first example balun circuit for implementation of the balun circuit of FIGS. 1A-1E;

FIGS. 6A-6D are a series of graphical representations respectively showing amplitude imbalance, phase imbalance, return loss, and insertion loss for the first example balun circuit of FIG. 5;

FIG. 7 shows a first example balun circuit for implementation of the balun circuit of FIGS. 1A-1E;

FIGS. 8A-8D are a series of graphical representations respectively showing amplitude imbalance, phase imbalance, return loss, and insertion loss for the first example balun circuit of FIG. 7; and

FIG. 9 is a process flow chart showing an example method for conversion of a single-ended signal to a differential signal by the balun circuit of FIGS. 1A-1E.

Corresponding reference characters indicate corresponding elements among the view of the drawings. The headings used in the figures do not limit the scope of the claims.

### DETAILED DESCRIPTION

Various embodiments of a system and associated methods for conversion of a single-ended source signal to an output differential signal using baluns optimized for wideband balance are disclosed herein. In particular, the present disclosure provides systems and methods for a circuit topology that addresses bandwidth limitations of baluns by symmetrically splitting the signal to generate signal pairs of equal amplitude and introducing a phase delay to the signal pairs. As the balance properties of such circuit topology disclosed herein enable a very wide bandwidth, other performance properties, such as matching and insertion loss which can also limit the operating bandwidth, can be addressed separately with full attention without the concerns of phase and amplitude balance. Further, the circuit topology discussed herein enables consideration of design tradeoffs (e.g., pertaining to loss, size and cost) without affecting the balance properties that are crucial for analog-to-digital conversion (ADC) applications.

Baluns are used to convert signals from single-ended to differential. Baluns split an input signal into two equal magnitude paths having a phase difference of 180-degrees relative to one another. When using baluns in the front-end circuitry of high-speed ADC devices, the magnitude imbalance, and phase imbalance of the balun are the key parameters that affect performance of an analog-to-digital converter. Any imbalance introduced by the balun in front end circuitry would result in overall data conversion degradation. With the market and applications driving ADC technology advances toward wider frequency bands. The front end circuitry, especially balun, are becoming a bottleneck of demonstrating the latest high-speed ADC integrated circuits chip in the full potential of its bandwidth and performance. There is a compelling urgency in the industry to find a type of balun improved balance properties in a wide operating frequency range for the high-speed ADC market.

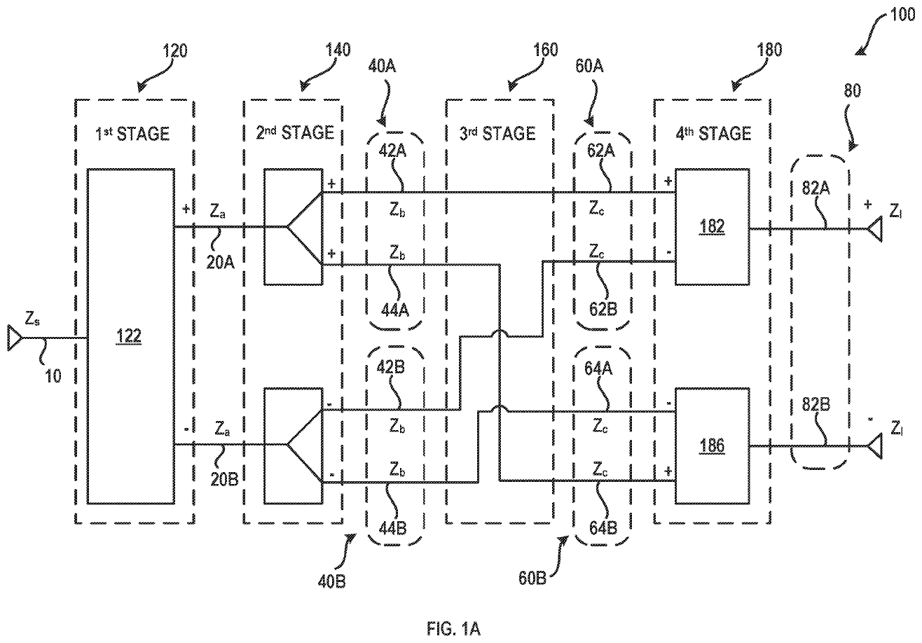

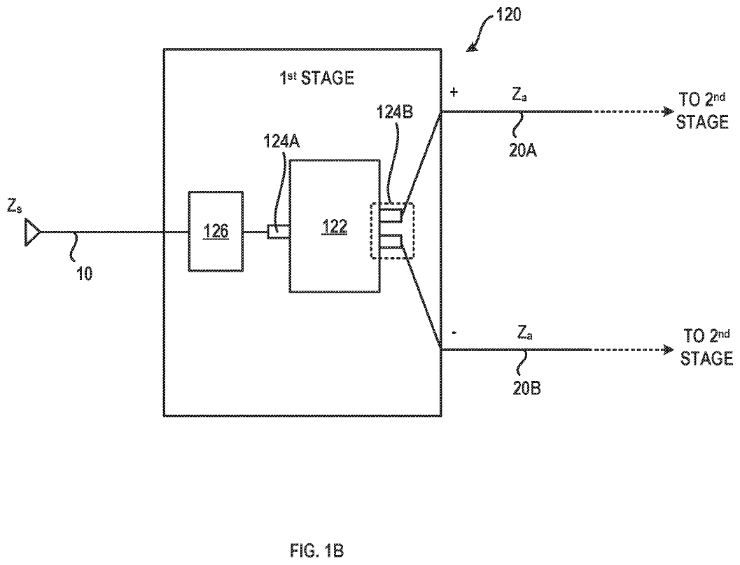

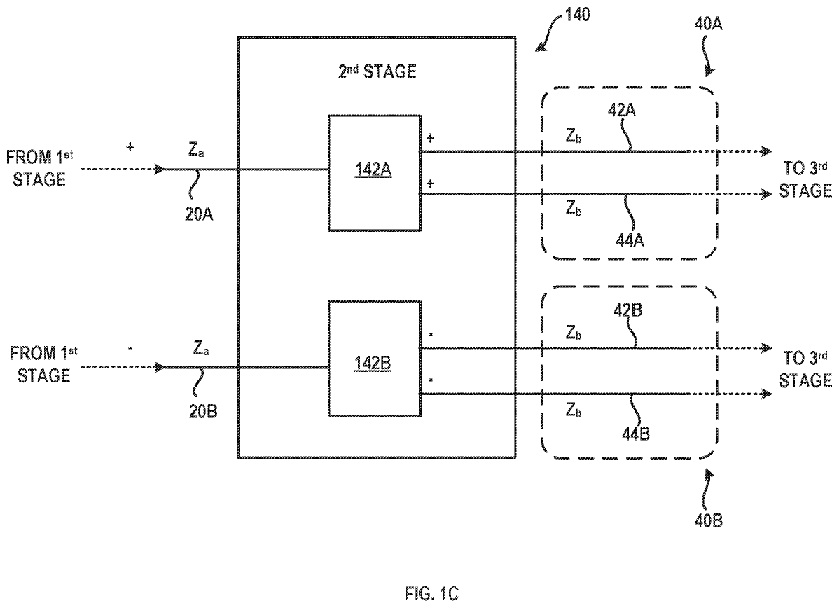

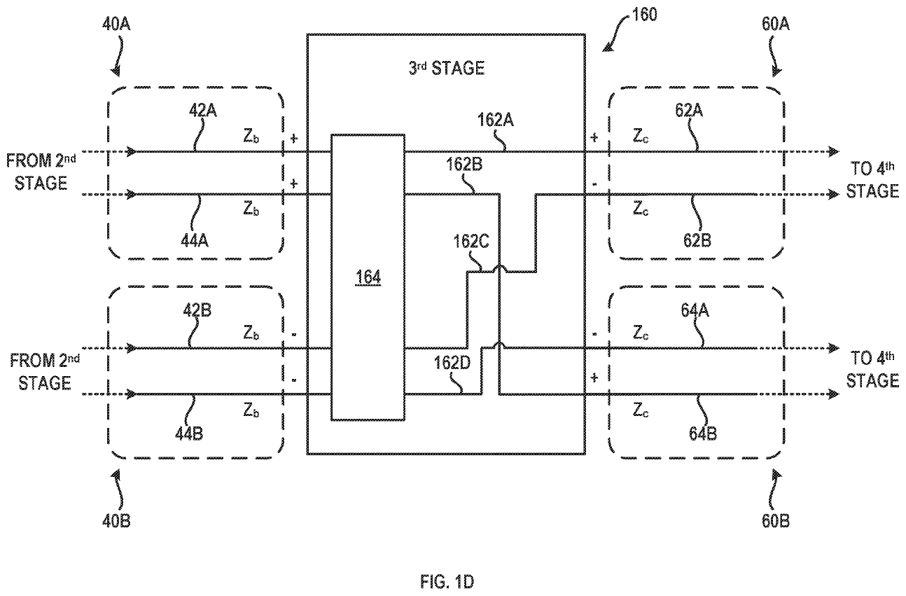

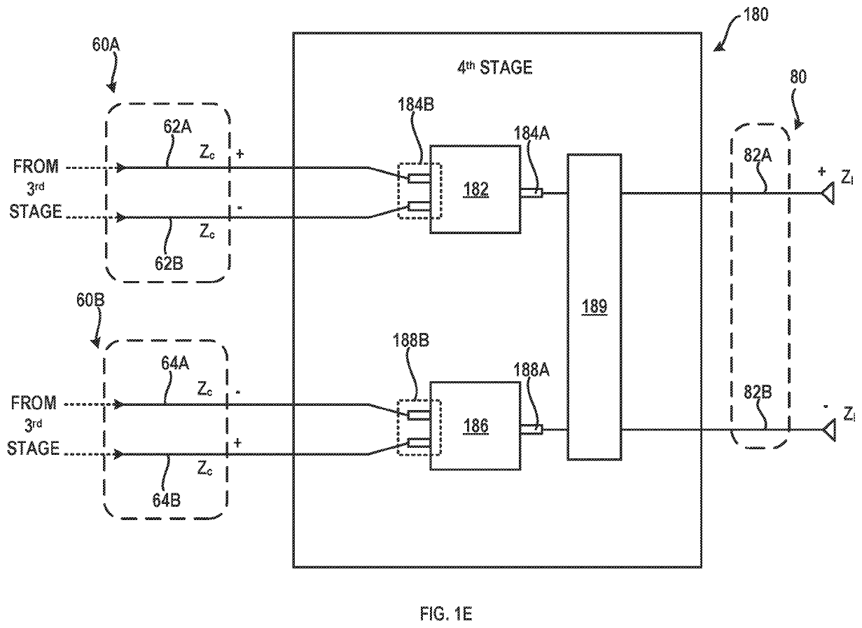

With reference to FIG. 1A, a balun circuit 100 for balanced conversion of a single-ended source signal to an output differential signal includes a first sub-circuit 120 that receives a single-ended source signal 10 and divides the single-ended source signal 10 into a first-stage positive signal 20A and a first-stage negative signal 20B. The first sub-circuit 120 includes a frontend balun 122 having a single-ended port 124A that receives the single-ended source signal 10 and a differential port 124B that outputs the first-stage positive signal 20A and the first-stage negative signal 20B. The first-stage positive signal 20A and the first-stage negative signal 20B collectively define a common mode signal introduced at the first sub-circuit 120 by the frontend balun 122.

The balun circuit 100 further includes a second sub-circuit 140 that receives the first-stage positive signal 20A and the first-stage negative signal 20B. The second sub-circuit 140 splits the first-stage positive signal 20A into a positive second-stage signal pair 40A having a first second-stage positive signal 42A and a second second-stage positive signal 44A, and simultaneously splits the first-stage negative signal 20B into a negative second-stage signal pair 40B having a first second-stage negative signal 42B and a second second-stage negative signal 44B (e.g., to yield a total of four signals from the original single-ended source signal).

The balun circuit 100 further includes a third sub-circuit 160 that introduces a phase delay by swapping the first second-stage positive signal 42A of the positive second-stage signal pair 40A with a first second-stage negative signal 42B of the negative second-stage signal pair 40B, yielding a first third-stage differential pair 60A having a first third-stage positive signal 62A and a first third-stage negative signal 62B and a second third-stage differential pair 60B having a second third-stage negative 64A signal and a second third-stage positive signal 64B. The third sub-circuit 160 introduces the phase delay by swapping positive and negative signals in a symmetric manner with minimal complexity and eliminating the need for a single-ended phase inverter implemented by current technologies, thus making the system easier to balance.

The balun circuit 100 further includes a fourth sub-circuit 180 that combines the first third-stage positive signal 62A and the first third-stage negative signal 62B of the first third-stage differential pair 60A to yield an output-stage positive signal 82A of an output differential signal 80; simultaneously, the fourth sub-circuit 180 combines the second third-stage negative signal 64A and the second third-stage positive signal 64B of the first third-stage differential pair 60A to yield an output-stage negative signal 82B of the output differential signal 80. The fourth sub-circuit 180 can include a first backend balun 182 having a single-ended port 184A associated with the output-stage positive signal 82A of the output differential signal 80 and having a differential port 184B associated with the first third-stage differential pair 60A, and a second backend balun 186 having a single-ended port 188A associated with the output-stage negative signal 82B of the output differential signal 80 and having a differential port 188B associated with the second third-stage differential pair 60B. The first backend balun 182 and the second backend balun 186 collectively reject the common-mode signal introduced at the first sub-circuit 120 by the frontend balun 122.

The frontend balun 122 of the first sub-circuit 120 introduces imperfect phase and magnitude splitting to the single-ended source signal 10 such that the common mode signal propagates along with the differential signal (e.g., the first-stage positive signal 20A and the first-stage negative signal 20B). At the fourth sub-circuit 180, the first backend balun 182 and the second backend balun 186 each have a common mode rejection property that rejects the common mode signal and reflects the common mode signal back toward the respective differential ports 184B and 188B of the first backend balun 182 and the second backend balun 186, showing as an input mismatch or an input return loss; as a result, the output differential signal 80 retains superb balance properties as desired by ADC applications.

FIG. 1B shows an example implementation of the first sub-circuit 120. As discussed, the first sub-circuit 120 can include the frontend balun 122 that converts the single-ended source signal 10 to the first-stage positive signal 20A and the first-stage negative signal 20B. A source impedance of Zₛ associated with the single-ended source signal 10 can be at the single-ended port 124A of the frontend balun 122; likewise, a load impedance of Zₐ associated with each individual output signal (e.g., the the first-stage positive signal 20A and the first-stage negative signal 20B) can be observed at each “line” of the differential port 124B of the frontend balun 122 for a total load impedance of 2* Zₐ as shown. The frontend balun 122 converts the single-ended source signal 10 into a differential signal including the first-stage positive signal 20A and the first-stage negative signal 20B, and does not necessarily need to present superb balance properties in full operating bandwidth at the first sub-circuit; in fact, it is expected that the frontend balun 122 exhibits imperfect phase and magnitude splitting and thus introduces the common mode signal that propagates along with the differential signal which will eventually be corrected at the fourth sub-circuit 180. Impedance transformation of the first sub-circuit 120 (e.g., from source impedance Zs to load impedance 2*Za), can be achieved by the natural properties of the frontend balun 122, and can optionally include a first-stage impedance matching network 126 at the single-ended port 124A or at the differential port 124B of the frontend balun 122 as shown.

FIG. 1C illustrates an example implementation of the second sub-circuit 140 that receives the first-stage positive signal 20A and the first-stage negative signal 20B and outputs two differential pairs including the positive second-stage signal pair 40A having the first second-stage positive signal 42A and the second second-stage positive signal 44A, and the negative second-stage signal pair 40B having the first second-stage negative signal 42B and the second second-stage negative signal 44B. The second sub-circuit 140 can be an amplitude splitting network that includes a first power divider network 142A and a second power divider network 142B placed in parallel as shown. The first power divider network 142A splits the first-stage positive signal 20A into the positive second-stage signal pair 40A having the first second-stage positive signal 42A and the second second-stage positive signal 44A; similarly, the second power divider network 142B splits the first-stage negative signal 20B into the negative second-stage signal pair 40B having the first second-stage negative signal 42B and the second second-stage negative signal 44B. The topologies of the first power divider network 142A and the second power divider network 142B are desired to be symmetrical such that the positive second-stage signal pair 40A and the negative second-stage signal pair 40B have equal magnitude and phase delay at any frequency point; as such, the first power divider network 142A and the second power divider network 142B can be identical. The first power divider network 142A and the second power divider network 142B can each be of any suitable form of splitting circuitry, with source impedances of Zₐ and load impedances of Z_{b} as shown. For example, the first power divider network 142A and the second power divider network 142B can each be a node splitter. In other examples, the first power divider network 142A and the second power divider network 142B can each include an RCL (resistor/capacitor/inductor) power divider network. Alternatively, the first power divider network 142A and the second power divider network 142B can include one or more single-stage or multi-stage Wilkinson power dividers. After this stage, the single-ended source signal 10 is divided equally into the positive second-stage signal pair 40A and the negative second-stage signal pair 40B, where the positive second-stage signal pair 40A and the negative second-stage signal pair 40B are two interlaced differential pairs of differential impedance 2*Z_{b}.

With reference to FIG. 1D, the third sub-circuit 160 introduces a wideband 180-degree phase delay by swapping the first second-stage positive signal 42A of the positive second-stage signal pair 40A with the first second-stage negative signal 42B of the negative second-stage signal pair 40B. In the example shown, the third sub-circuit 160 can include four transmission paths 162A-162D of equal phase delay with crossovers, if needed, to rearrange or otherwise “swap” polarities of the positive second-stage signal pair 40A and the negative second-stage signal pair 40B into the first third-stage differential pair 60A having polarities of positive and negative output and the second third-stage differential pair 60B having opposite polarities of negative and positive output. The first third-stage differential pair 60A includes the first third-stage positive signal 62A and the first third-stage negative signal 62B, and the second third-stage differential pair 60B includes the second third-stage negative signal 64A and the second third-stage positive signal 64B; as such, the third sub-circuit 160 introduces a wideband 180-degree relative phase delay between the first third-stage differential pair 60A and the second third-stage differential pair 60B. In some embodiments, the four transmission paths 162A-162D of the third sub-circuit 160 can simply include four transmission lines each having a characteristic impedance of Z_{b}. Further, in some embodiments the third sub-circuit 160 can also include a third-stage impedance matching network 164 that transforms a source impedance of Z_{b} for each transmission path to a load impedance of Z_{c}. After this stage, single-ended source signal 10 is converted into the first third-stage differential pair 60A and the second third-stage differential pair 60B, which are of equal magnitude and have a wideband 180-degree phase delay as shown.

FIG. 1E shows an example implementation of the fourth sub-circuit 180 that converts the first third-stage differential pair 60A and the second third-stage differential pair 60B (4 signal paths total) into the output differential signal 80 (2 signal paths total). As discussed, the fourth sub-circuit 180 can include the first backend balun 182 and the second backend balun 186. The first backend balun 182 can include the differential port 184B that receives the first third-stage differential pair 60A and the single-ended port 184A that outputs the output-stage positive signal 82A of the output differential signal 80; likewise, the second backend balun 186 can include the differential port 188B that receives the second third-stage differential pair 60B and the single-ended port 188A that outputs the output-stage negative signal 82B of the output differential signal 80. As shown, the differential ports 184B and 188B of the first backend balun 182 and the second backend balun 186 can each have a port impedance of 2*Zc (e.g., Zc for each individual port relative to ground), and the single-ended ports 184A and 188A of the first backend balun 182 and the second backend balun 186 can each have a port impedance of Z_{I}. Impedance transformation of the fourth sub-circuit 180 (e.g., from single-ended port impedance Z_{I} to differential port impedance 2*Z_{c}) can be achieved by the natural circuit properties of the first backend balun 182 and the second backend balun 186 and can optionally include a fourth-stage impedance matching network 189 at the single-ended ports 184A and 188A or at the differential ports 184B and 188B of each respective first backend balun 182 and second backend balun 186 as shown (note that while FIG. 1E shows the fourth-stage impedance matching network 189 at the single-ended ports 184A and 188A, the fourth-stage impedance matching network 189 could also be implemented at the differential ports 184B and 188B). The purpose of the first backend balun 182 and the second backend balun 186 is to convert each respective differential signal (e.g., the first third-stage differential pair 60A and the second third-stage differential pair 60B) back into respective single-ended signals with opposing polarities (e.g., the output-stage positive signal 82A and the output-stage negative signal 82B that collectively define the output differential signal 80). As discussed, the first backend balun 182 and the second backend balun 186 collectively reject the common-mode signal introduced due to natural imperfections in the first-stage positive signal 20A and the first-stage negative signal 20B produced by the frontend balun 122 of the first sub-circuit 120. After conversion by the fourth sub-circuit 180, the output-stage positive signal 82A and the output-stage negative signal 82B have equal magnitude and a 180-degree phase delay relative to one another, forming the output differential signal 80 which is a new differential signal based on the single-ended source signal 10 with a differential port impedance of 2*Z_{I}.

### Impedance Matching

Using the balun circuit 100 discussed herein, the overall bandwidth of the entire network as an overall balun can be addressed focusing on the impedance matching, without the distraction of concerns of amplitude and phase balancing. With complexity and insertion loss in consideration, the impedance matching bandwidth can be optimized with different kinds of practical implementations at each stage.

The flexibility of balun selection for the frontend balun 122 of the first sub-circuit 120, and the first backend balun 182 and the second backend balun 186 of the fourth sub-circuit 180 enables bandwidth optimization through impedance matching. For example, a conventional Marchand balun can offer a flexible impedance transforming ratio, but is typically limited to about 1:3 relative frequency bandwidth. A Guanella balun has greatest operating bandwidth in terms of return loss, but can only offer a few fixed impedance ratios: 1:1 and 1:4 and 1:2, with a bit more complexity. Guanella baluns are typically good wideband choices for frontend and backend baluns if the available impedance transforming meets the requirements. Additional impedance matching networks (e.g., the first-stage impedance matching network 126 and/or the fourth-stage impedance matching network 189) including multi-section transmission lines or an RLC (resistor/inductor/ capacitor) lump element network can be added at the single-ended port 124A or the differential port 124B of the frontend balun 122, the single-ended port 184A or the differential port 184B of the first backend balun 182 and the single-ended port 188A or the differential port 188B of the second backend balun 186.

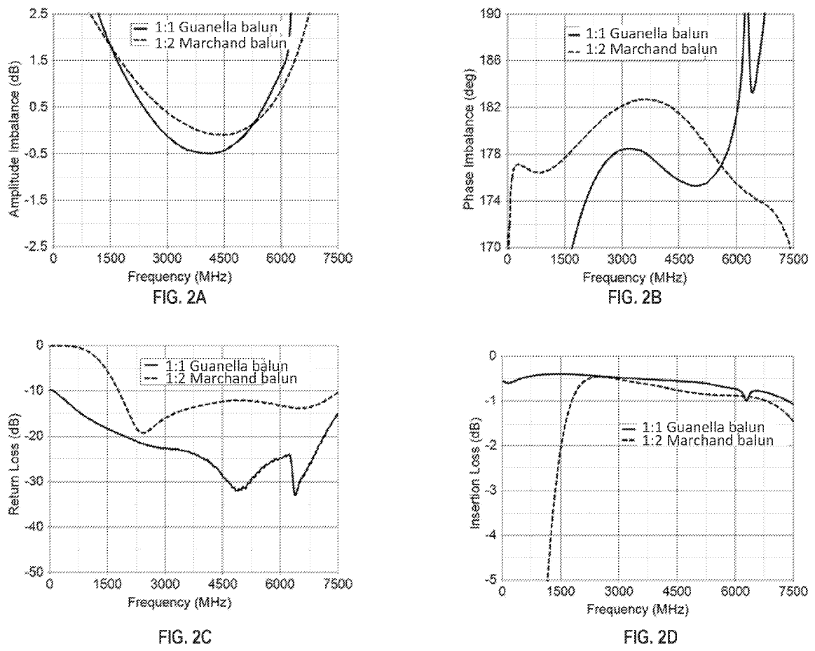

FIGS. 2A-2D compare performances of a 1:1 Guanella balun (solid line) with a 1:2 Marchand balun for amplitude imbalance (FIG. 2A), phase imbalance (FIG. 2B), return loss (FIG. 2C) and insertion loss (FIG. 2D) across a wide range of frequencies. As shown, with the specifications of 10 dB return loss, ±1.5 dB amplitude imbalance, and ±10 degrees of phase imbalance, the bandwidth of either balun is only about 1600 MHz to 6000 MHz. Both amplitude and phase imbalance deteriorate quickly outside the 1600-6000 MHz band, limiting the bandwidth.

Impedance matching can also be implemented at the splitting network of the second sub-circuit 140 with a multi-section transmission line, such as a Wilkinson power divider or an RLC lump element network, at the cost of adding the design complexity and insertion loss. The widest bandwidth and lowest insertion loss can be achieved when the load impedance Z_{b} of the first power divider network 142A and the load impedance Z_{b} of the second power divider network 142B is two times the source impedance Zₐ (Z_{b}=2*Zₐ). With this impedance ratio, the first power divider network 142A can include a single node that connects the first-stage positive signal 20A of port impedance of Zₐ and outputs two dividing branches that form the positive second-stage signal pair 40A including the first second-stage positive signal 42A and the second second-stage positive signal 44A with port impedance of Z_{b}=2*Zₐ; likewise, the second power divider network 142B can include a single node that connects the first-stage negative signal 20B of port impedance of Zₐ and outputs two dividing branches that form the negative second-stage signal pair 40B including the first second-stage negative signal 42B and the second second-stage negative signal 44B with port impedance of Z_{b}=2*Zₐ. Such an arrangement would naturally split the first-stage positive signal 20A and the first-stage negative signal 20B in half and match the impedance for all the frequencies.

Impedance matching can also be implemented in the phase delay network of the third sub-circuit 160, with the third-stage impedance matching network 164 including a multi-section transmission line or an RLC lump element network, at the cost of adding increased design complexity and insertion loss. The widest bandwidth and lowest insertion loss can be achieved when the impedance transforming ratio of the third sub-circuit 160 is one (e.g., Z_{b}=Z_{c}). In this case, a set of four short transmission lines of characteristic impedance Z_{b} would have the lossless matching for all the frequencies.

### Implementation Examples

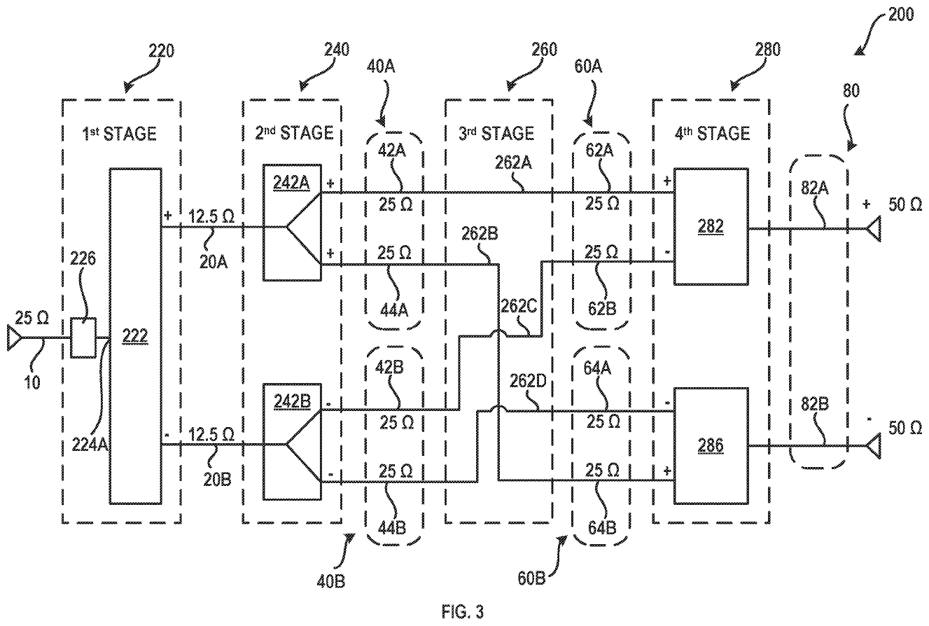

FIG. 3 shows a first example balun circuit 200 that includes a first sub-circuit 220, a second sub-circuit 240, a third sub-circuit 260 and a fourth sub-circuit 280 and implements an overall 4-stage cascaded balun of 25 Ω single-ended to 100 Ω differential.

A 25 Ω to 25 Ω balun (paralleling two TTM RF&S P/N X4B40L1-5050G baluns) is used at the first sub-circuit 220 as a frontend balun 222 to convert the single-ended source signal 10 into the first-stage positive signal 20A and the first-stage negative signal 20B. The second sub-circuit 240 can include a first node splitter as a first power divider network 242A and a second node splitter as a second power divider network 242B that split each of the first-stage positive signal 20A and the first-stage negative signal 20B (having impedances of 12.5 Ω each) into two parallel 25 Ω splitting paths forming the positive second-stage signal pair 40A having the first second-stage positive signal 42A and the second second-stage positive signal 44A, and forming the negative second-stage signal pair 40B having the first second-stage negative signal 42B and the second second-stage negative signal 44B. Four 25 Ω transmission lines 262A-262D are used at the third sub-circuit 260 for the phase delay network to swap the polarities of the positive second-stage signal pair 40A and the negative second-stage signal pair 40B resulting in the first third-stage differential pair 60A having the first third-stage positive signal 62A and the first third-stage negative signal 62B and the second third-stage differential pair 60B having the second third-stage negative signal 64A and the second third-stage positive signal 64B. At the fourth sub-circuit 280, two 50 Ω to 50 Ω baluns (TTM RF&S P/N X4B40L1-5050G) are used as a first backend balun 282 and a second backend balun 286 to combine the first third-stage differential pair 60A into the output-stage positive signal 82A of the output differential signal 80 and to combine the first third-stage differential pair 60A into the output-stage negative signal 82B of the output differential signal 80.

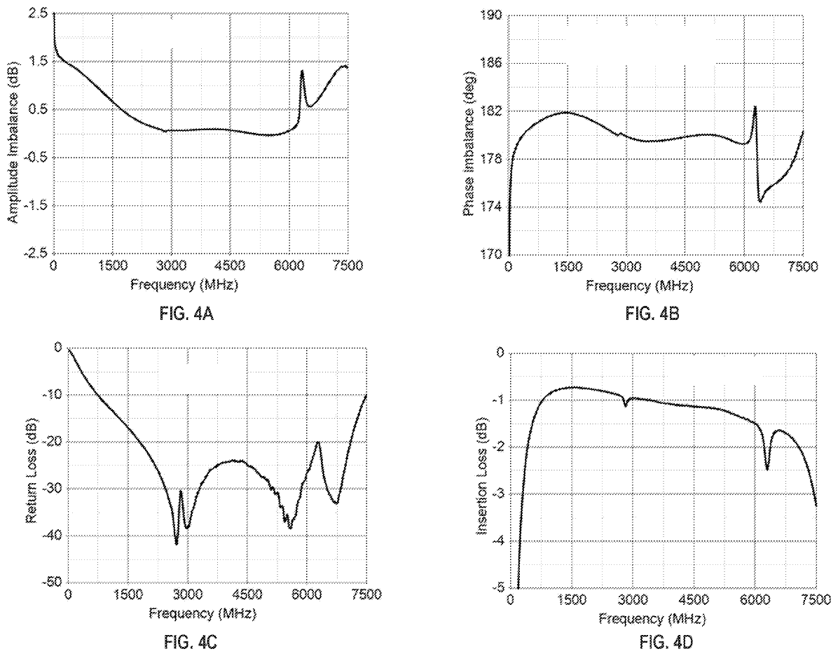

FIGS. 4A-4D show performance of the first example balun circuit 200 for amplitude imbalance (FIG. 4A), phase imbalance (FIG. 4B), return loss (FIG. 4C) and insertion loss (FIG. 4D) across a wide range of frequencies. If the total balun of the balun circuit 200 has to satisfy the same specification of 10 dB return loss, ±1.5 dB amplitude imbalance, ±10 degrees of phase imbalance, the overall 25 Ω single-ended to 100 Ω differential balun of the balun circuit 200 has the bandwidth of 700 MHz to 7500 MHz while the original baluns shown in FIGS. 2A-2D have only the bandwidth of 1600 MHz to 6000 MHz.

In addition, if an overall balun of single-ended 50 Ω is desired, impedance matching can be applied at a single-ended port 224A of the frontend balun 222 of the first sub-circuit 220, adding a multi-section quarter-wavelength transmission line impedance transformer or simply a resistor (e.g., as a first-stage impedance matching network 226) without hurting the amplitude and phase imbalance.

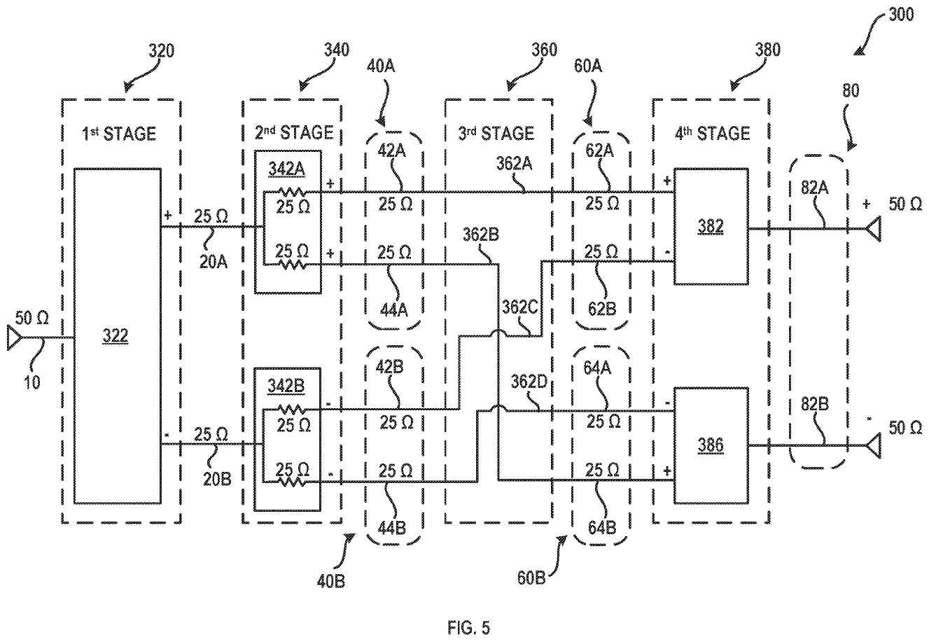

FIG. 5 shows a second example balun circuit 300 that includes a first sub-circuit 320, a second sub-circuit 340, a third sub-circuit 360 and a fourth sub-circuit 380 and implements an overall balun of single-ended 50 Ω and differential 100 Ω.

A 50 Ω to 50 Ω balun (TTM RF&S P/N X4B40L1-5050G) is used at the first sub-circuit 320 as a frontend balun 322 to convert the single-ended source signal 10 into the first-stage positive signal 20A and the first-stage negative signal 20B. The second sub-circuit 340 can include a first resistive divider as a first power divider network 342A and a second resistive divider as a second power divider network 342B that split each of the first-stage positive signal 20A and the first-stage negative signal 20B (having impedances of 25 Ω each) into two 25 Ω splitting paths forming the positive second-stage signal pair 40A having the first second-stage positive signal 42A and the second second-stage positive signal 44A, and forming the negative second-stage signal pair 40B having the first second-stage negative signal 42B and the second second-stage negative signal 44B. Four 25 Ω transmission lines 362A-362D are used at the third sub-circuit 360 for the phase delay network to swap the polarities of the positive second-stage signal pair 40A and the negative second-stage signal pair 40B resulting in the first third-stage differential pair 60A having the first third-stage positive signal 62A and the first third-stage negative signal 62B and the second third-stage differential pair 60B having the second third-stage negative 64A signal and the second third-stage positve signal 64B. At the fourth sub-circuit 380, two 50 Ω to 50 Ω baluns (TTM RF&S P/N X4B40L1-5050G) are used as a first backend balun 382 and a second backend balun 386 to combine the first third-stage differential pair 60A into the output-stage positive signal 82A of the output differential signal 80 and to combine the first third-stage differential pair 60A into the output-stage negative signal 82B of the output differential signal 80.

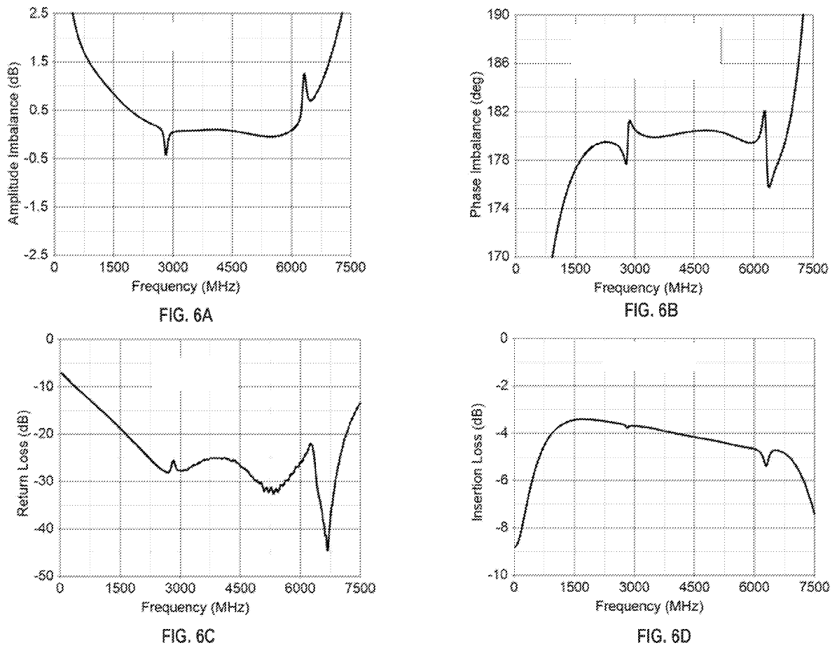

FIGS. 6A-6D show performance of the second example balun circuit 300 for amplitude imbalance (FIG. 6A), phase imbalance (FIG. 6B), return loss (FIG. 6C) and insertion loss (FIG. 6D) across a wide range of frequencies. If the overall balun of the second example balun circuit 300 has to satisfy the specification of 10 dB return loss, ±1.5 dB amplitude balance, ±10 degrees of phase balance, the overall 50 Ω single-ended to 100 Ω differential balun has the bandwidth of 900 MHz to 7000 MHz while the original baluns shown in FIGS. 2A-2D have only the bandwidth of 1600 to 6000 MHz.

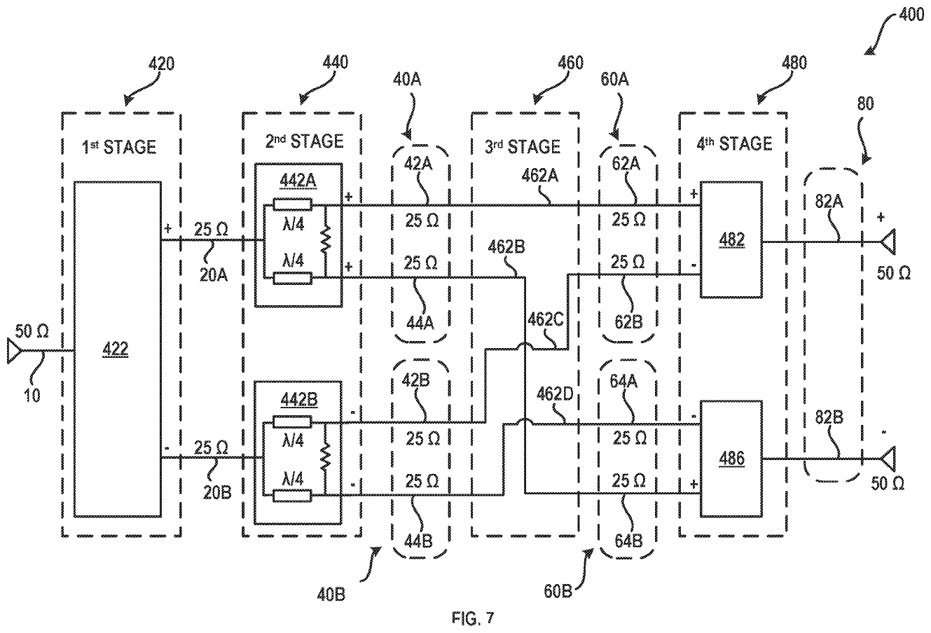

FIG. 7 shows a third example balun circuit 400 that includes a first sub-circuit 420, a second sub-circuit 440, a third sub-circuit 460 and a fourth sub-circuit 480 and implements an overall balun of single-ended 50 Ω and differential 100 Ω.

A 50 Ω to 50 Ω balun (TTM RF&S P/N X4B40L1-5050G) is used at the first sub-circuit 420 as a frontend balun 422 to convert the single-ended source signal 10 into the first-stage positive signal 20A and the first-stage negative signal 20B. The second sub-circuit 440 can include a first single-stage Wilkinson power divider as a first power divider network 442A and a second single-stage Wilkinson power divider as a second power divider network 442B that split each of the first-stage positive signal 20A and the first-stage negative signal 20B (having impedances of 25 Ω each) into two 25 Ω splitting paths forming the positive second-stage signal pair 40A having the first second-stage positive signal 42A and the second second-stage positive signal 44A, and forming the negative second-stage signal pair 40B having the first second-stage negative signal 42B and the second second-stage negative signal 44B. Four 25 Ω transmission lines 462A-462D are used at the third sub-circuit 460 for the phase delay network to swap the polarities of the positive second-stage signal pair 40A and the negative second-stage signal pair 40B resulting in the first third-stage differential pair 60A having the first third-stage positive signal 62A and the first third-stage negative signal 62B and the second third-stage differential pair 60B having the second third-stage negative signal 64A and the second third-stage positive signal 64B. At the fourth sub-circuit 480, two 50 Ω to 50 Ω baluns (TTM RF&S P/N X4B40L1-5050G) are used as a first backend balun 482 and a second backend balun 486 to combine the first third-stage differential pair 60A into the output-stage positive signal 82A of the output differential signal 80 and to combine the first third-stage differential pair 60A into the output-stage negative signal 82B of the output differential signal 80.

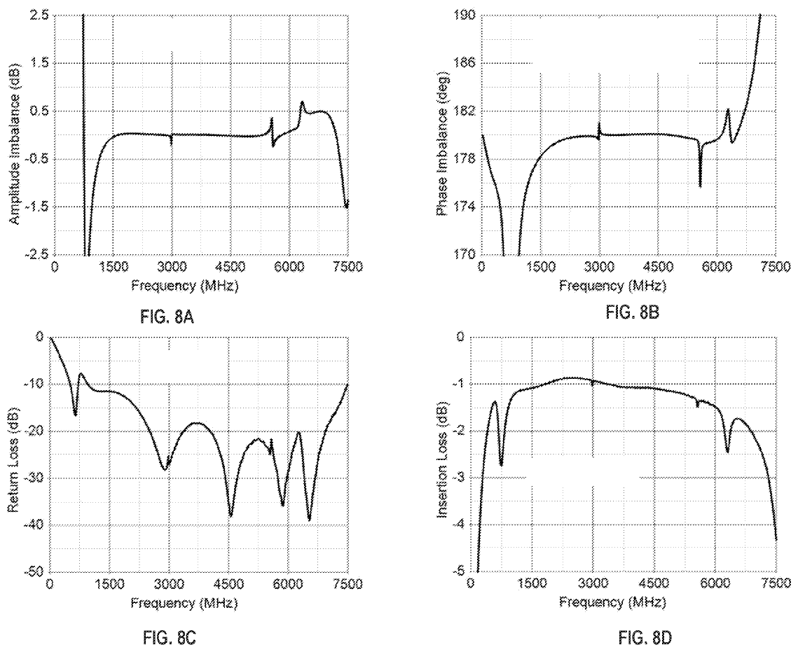

FIGS. 8A-8D show performance of the third example balun circuit 400 for amplitude imbalance (FIG. 8A), phase imbalance (FIG. 8B), return loss (FIG. 8C) and insertion loss (FIG. 8D) across a wide range of frequencies. If the overall balun of the third example balun circuit 400 has to satisfy the specification of 10 dB return loss, ±1.5 dB amplitude imbalance, ±10 degrees of phase imbalance, the overall 50 Ω single-ended to 100 Ω differential balun has the bandwidth of 1000 MHz to 7000 MHz while the original baluns shown in FIGS. 2A-2D have only the bandwidth of 1600 to 6000 MHz.

The arrangement of the third example balun circuit 400 exhibited superior flatness on both amplitude and phase imbalance responses over the conventional Guanella and Marchand Baluns. And if needed, the performance can be further improved by using a first multi-stage Wilkinson power divider as the first power divider network 442A in place of the first single-stage Wilkinson power divider and a second multi-stage Wilkinson power divider as the second power divider network 442B in place of the second single-stage Wilkinson power divider.

### Methods

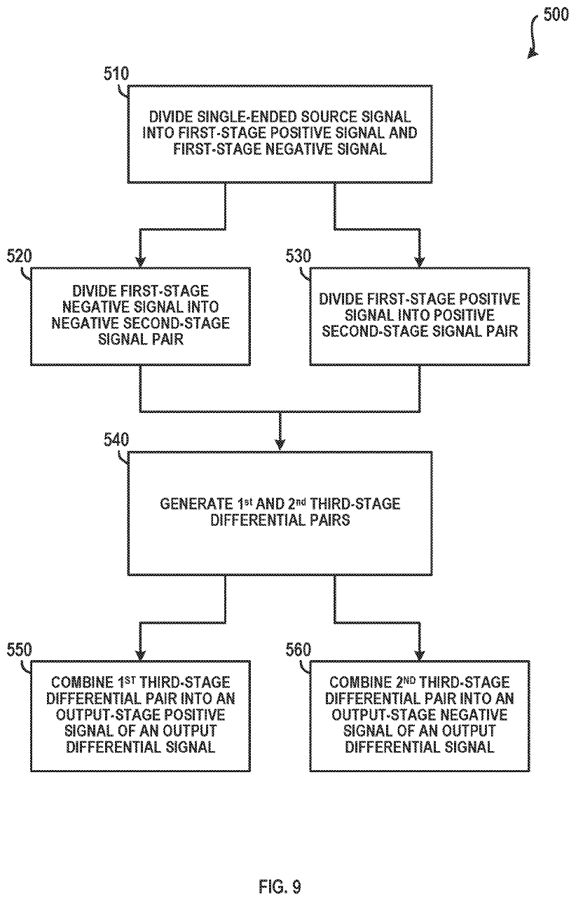

FIG. 9 shows a method 500 for conversion of a single-ended signal (e.g., single-ended signal 10) into an output differential signal (e.g., output differential signal 80) according to aspects of the present disclosure. A first step 510 of method 500 includes dividing, at a first sub-circuit (e.g., first sub-circuit 120, 220, 320 or 420 discussed above), a single-ended source signal into a first-stage positive signal and a first-stage negative signal, where the first-stage positive signal and the first-stage negative signal collectively define a common mode signal introduced at the first sub-circuit. Step 520 of method 500 includes dividing, at a second sub-circuit (e.g., second sub-circuit 140, 240, 340 or 440 discussed above), the first-stage positive signal into a positive second-stage signal pair having a first second-stage positive signal and a second second-stage positive signal. Step 530 of method 500 can be applied simultaneously with step 520 and includes dividing, at the second sub-circuit, the first-stage negative signal into a negative second-stage signal pair having a first second-stage negative signal and a second second-stage negative signal. Step 540 of method 500 includes swapping, at a third sub-circuit (e.g., third sub-circuit 160, 260, 360 or 460 discussed above), the first second-stage positive signal of the positive second-stage signal pair with a first negative signal of the negative second-stage signal pair yielding a first third-stage differential pair having a first third-stage positive signal and a first third-stage negative signal and a second third-stage differential pair having a second third-stage negative signal and a second third-stage positive signal. Step 550 of method 500 includes combining, at a fourth sub-circuit (e.g., fourth sub-circuit 180, 280, 380 or 480 discussed above), the first third-stage differential pair to yield an output-stage positive signal of an output differential signal. A final step 560 of method 500 includes combining, at the fourth sub-circuit, the second third-stage differential pair to yield an output-stage negative signal of the output differential signal.

It should be understood from the foregoing that, while particular embodiments have been illustrated and described, various modifications can be made thereto without departing from the spirit and scope of the invention as will be apparent to those skilled in the art. Such changes and modifications are within the scope and teachings of this invention as defined in the claims appended hereto.

What is claimed is:

1. A circuit for conversion of a single-ended source signal to an output differential signal, the circuit comprising:
a first sub-circuit configured to divide a single-ended source signal into a first-stage positive signal and a first-stage negative signal;
a second sub-circuit configured to divide the first-stage positive signal into a positive second-stage signal pair having a first second-stage positive signal and a second second-stage positive signal and configured to divide the first-stage negative signal into a negative second-stage signal pair having a first second-stage negative signal and a second second-stage negative signal;
a third sub-circuit configured to swap the first second-stage positive signal of the positive second-stage signal pair with a first negative signal of the negative second-stage signal pair yielding a first third-stage differential pair having a first third-stage positive signal and a first third-stage negative signal and a second third-stage differential pair having a second third-stage positive signal and a second third-stage negative signal; and
a fourth sub-circuit configured to combine the first third-stage differential pair to yield an output-stage positive signal of an output differential signal and configured to combine the second third-stage differential pair to yield an output-stage negative signal of the output differential signal.

2. The circuit of claim 1, wherein the first sub-circuit includes:
a frontend balun having a single-ended port associated with the single-ended source signal and a differential port associated with the first-stage positive signal and the first-stage negative signal.

3. The circuit of claim 2, wherein the first sub-circuit includes an impedance matching network in combination with the frontend balun.

4. The circuit of claim 1, wherein the second sub-circuit includes:
a first power divider network that converts the first-stage positive signal into the positive second-stage signal pair; and
a second power divider network that converts the first-stage negative signal into the negative second-stage signal pair.

5. The circuit of claim 4, wherein the first power divider network includes a first node splitter and wherein the second power divider network includes a second node splitter.

6. The circuit of claim 4, wherein the first power divider network and the second power divider network include an RLC power divider network.

7. The circuit of claim 4, wherein the first power divider network and the second power divider network include one or more Wilkinson power dividers.

8. The circuit of claim 1, wherein the positive second-stage signal pair and the negative second-stage signal pair have equal magnitude and equal phase delay within each pair across a plurality of frequency points.

9. The circuit of claim 1, wherein the second sub-circuit includes an impedance matching network.

10. The circuit of claim 1, wherein the second sub-circuit defines a source impedance and a load impedance and wherein the load impedance of the second sub-circuit is equal to two times the source impedance.

11. The circuit of claim 1, wherein the first third-stage positive signal and the first third-stage negative signal are equal in amplitude and have opposing polarities relative to one another; and wherein the second third-stage negative signal and the second third-stage positive signal are equal in amplitude and have opposing polarities relative to one another.

12. The circuit of claim 1, wherein the fourth sub-circuit includes:
a first backend balun having a differential port associated with the first third-stage differential pair and a single-ended port associated with the output-stage positive signal of the output differential signal; and
a second backend balun having a differential port associated with the second third-stage differential pair and a single-ended port associated with the output-stage negative signal of the output differential signal.

13. The circuit of claim 1, wherein the fourth sub-circuit includes an impedance matching network in combination with a first backend balun and a second backend balun.

14. The circuit of claim 1, wherein the output-stage negative signal and the output-stage positive signal of the output differential signal are equal in amplitude and have opposing polarities relative to one another.

15. The circuit of claim 1, wherein the first-stage positive signal and the first-stage negative signal collectively define a common mode signal introduced at the first sub-circuit and wherein the fourth sub-circuit rejects the common mode signal introduced at the first sub-circuit.

16. A method for conversion of a single-ended source signal to an output differential signal; the method comprising:
dividing, at a first sub-circuit, a single-ended source signal into a first-stage positive signal and a first-stage negative signal;
dividing, at a second sub-circuit, the first-stage positive signal into a positive second-stage signal pair having a first second-stage positive signal and a second second-stage positive signal;
dividing, at the second sub-circuit, the first-stage negative signal into a negative second-stage signal pair having a first second-stage negative signal and a second second-stage negative signal;
swapping, at a third sub-circuit, the first second-stage positive signal of the positive second-stage signal pair with a first negative signal of the negative second-stage signal pair yielding a first third-stage differential pair having a first third-stage positive signal and a first third-stage negative signal and a second third-stage differential pair having a second third-stage negative signal and a second third-stage positive signal; and
combining, at a fourth sub-circuit, the first third-stage differential pair to yield an output-stage positive signal of an output differential signal;
combining, at the fourth sub-circuit, the second third-stage differential pair to yield an output-stage negative signal of the output differential signal.

17. The method of claim 16, wherein the first sub-circuit includes:
a frontend balun having a single-ended port associated with the single-ended source signal and a differential port associated with the first-stage positive signal and the first-stage negative signal.

18. The method of claim 16, wherein the second sub-circuit includes:
a first power divider network that converts the first-stage positive signal into the positive second-stage signal pair; and
a second power divider network that converts the first-stage negative signal into the negative second-stage signal pair.

19. The method of claim 16, wherein the second sub-circuit defines a source impedance and a load impedance and wherein the load impedance of the second sub-circuit is equal to two times the source impedance.

20. The method of claim 16, wherein the fourth sub-circuit includes:
a first backend balun having a differential port associated with the first third-stage differential pair and a single-ended port associated with the output-stage positive signal of the output differential signal; and
a second backend balun having a differential port associated with the second third-stage differential pair and a single-ended port associated with the output-stage negative signal of the output differential signal.

21. The method of claim 16, wherein the output-stage negative signal and the output-stage positive signal of the output differential signal are equal in amplitude and have opposing polarities relative to one another.

22. The method of claim 16, wherein the first-stage positive signal and the first-stage negative signal collectively define a common mode signal introduced at the first sub-circuit and wherein the fourth sub-circuit rejects the common mode signal introduced at the first sub-circuit.

23. A circuit for conversion of a single-ended source signal to an output differential signal according to any arrangement, configuration, or embodiment disclosed herein.

24. A method for conversion of a single-ended source signal to an output differential signal, comprising any arrangement, configuration, process, or embodiment disclosed herein.
